(19) United States
(12) Patent Application Publication
(10) Pub. No.: US 2010/0012369 A1
(43) Pub. Date: Jan. 21, 2010

(54) SPRING RETAINED SHIELD FOR PRINTED WIRING BOARDS

(76) Inventor: John Pope, San Clemente, CA (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(21) Appl. No.: 12/174,531

(22) Filed: Jul. 16, 2008

(51) Int. Cl. H05K 9/00

(52) U.S. Cl. 174/377

(57) ABSTRACT

A spring retained shield releasably securable to a printed wiring board (PWB). The shield preferably comprises a body that is compliant such that it bends under pressure and springs back to its original shape when released. The shield further comprises a releasable attachment mechanism that engages the PWB when the body is released or no longer under pressure. Preferably, the body has an open ended box shape with front and back walls, a top wall and first and second side walls. A passageway or cutout is formed in the front and back walls. The body is preferably formed of a conductive material. To releasably mount or couple the shield to a PWB, the releasable attachment mechanism comprises first and second mounting legs extending from the first side wall and third and fourth mounting legs extending from the second side wall.

### FIELD

The invention relates generally to shields for printed wiring boards and more particularly to a shield that facilitates releasably securing the shield to the printed wiring board.

### BACKGROUND INFORMATION

Printed wiring boards (PWB) are the foundation for virtually all electronics in the world, including televisions. It is the platform upon which electronic components such as processor and memory chips, capacitors and the like are mounted and through which these components are electrically interconnected. A PWB typically consists of a non-conducting substrate (e.g., fiberglass with epoxy resin) with a conductive pattern or circuitry formed there on from such conductors as copper, nickel, silver, tin, tin-lead, and gold. With its electronic components mounted thereon, the PWB forms the basic building block for all larger electronic systems, from toys to toasters to telecommunications.

A shield, typically box shaped and formed from a conductive material, is often placed over an electronic component or a portion of the circuitry on a PWB to protect the component or circuitry from electromagnetic radiation originating outside the shield or to protect adjacent circuits or components from electromagnetic energy originating inside of the shield. As electronic circuitry has been miniaturized and packed ever more tightly together, more and more shields are required for electrical isolation in the finished assembly.

Although shields can be fixedly mounted or attached to a PWB with solder or other know means, shields are preferably removably mounted to the surface of the PWB. Removability is desirable for providing access for test and repair. When the shield is not removable, the circuitry beneath the shield is inaccessible for test or repair once the shield is mounted in place. With a removable shield, the circuitry may be tested and repaired. Following the repair, the shield is replaced for proper operation of the assembly.

However, after install on a PWB, shields are often dislodged from their mount on the PWB during further assembly and/or processing. Accordingly, it would be desirable to provide a removeable shield that is securely fixed in place when mounted on the PWB.

### SUMMARY

The embodiments described herein are directed to systems and methods that provide for releasably securing a shield on a printed wiring board (PWB). The shield preferably comprises a body that is compliant such that it bends or is deformable under pressure and springs back or returns to its original shape when released. The shield further comprises a releasable attachment mechanism that engages the PWB when the body is released or no longer under pressure.

Preferably, the body has an open ended box shape with front and back walls, a top wall and first and second side walls. A passageway or cutout is formed in the front and back walls. The body is preferably formed of a conductive material.

To releasably mount or couple the shield to a PWB, the releasable attachment mechanism comprises first and second mounting legs extending from the first side wall and third and fourth mounting legs extending from the second side wall. The body is preferably compliant such that it is deformable with a spring like quality when squeezed or pressure is applied inwardly at opposing side walls. Once the side walls are released or the pressure is no longer applied inwardly, the side walls spring back or return to their original or relaxed position.

In operation, the installer squeezes the side walls of the shield inward slightly, enough to insert the shield legs into the mounting holes formed in the PWB. After inserting the legs into the mounting holes, the installer releases the sides of the shield, thus allowing the pressure of the mounting legs to be applied to the side surfaces of the mounting holes and prevent the shield from being inadvertently dislodged from the PWB during processing, assembly, and the like.

Other systems, methods, features and advantages of the invention will be or will become apparent to one with skill in the art upon examination of the following figures and detailed description.

### BRIEF DESCRIPTION OF THE FIGURES

The details of the invention, including fabrication, structure and operation, may be gleaned in part by study of the accompanying figures, in which like reference numerals refer to like parts. The components in the figures are not necessarily to scale, emphasis instead being placed upon illustrating the principles of the invention. Moreover, all illustrations are intended to convey concepts, where relative sizes, shapes and other detailed attributes may be illustrated schematically rather than literally or precisely.

FIG. 1 depicts a perspective view of a spring retained shield.

FIG. 2 depicts a perspective view of an exploded assembly of the spring retained shield and a printed wiring board.

FIG. 3 depicts a cross-sectional view taken along line 3-3 in FIG. 2.

### DETAILED DESCRIPTION

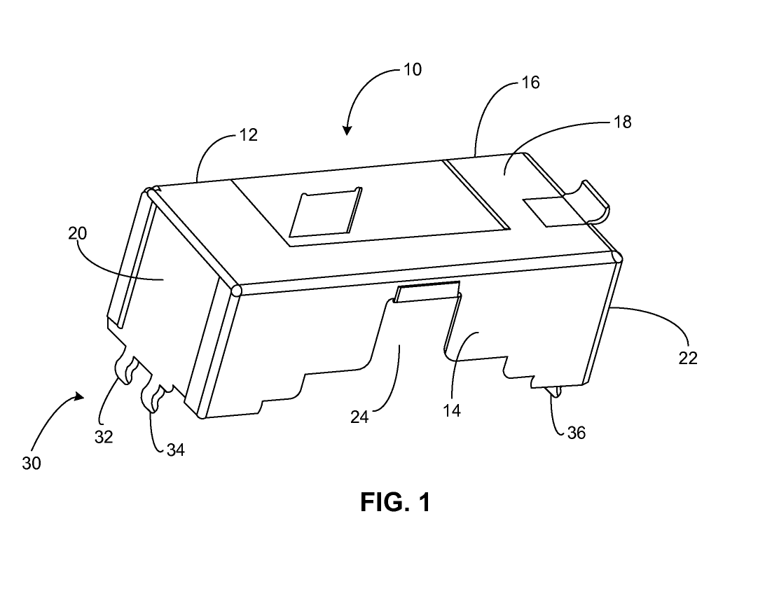

The systems and methods described herein provide for releasably securing a shield on a printed wiring board (PWB). Turning in detail to the figures, FIG. 1 depicts a spring retained shield 10 comprising an open ended box shaped body 12 with front and back walls 14 and 16, a top wall 18 and first and second side walls 20 and 22. A passageway or cutout 24 is formed in the front and back walls 14 and 16. The body 12 is preferably formed of a conductive material.

To releasably mount or couple the shield 10 to a PWB, the shield 10 includes a releasable attachment mechanism 30 comprising first and second legs 32 and 34 extending from the first side wall 20. The attachment mechanism 30 includes a third leg 36 shown extending from the second side wall 22 and a fourth leg (not shown) extending from the second side wall 22. The body 12 is preferably compliant such that it possesses a spring like quality when squeezed or pressure is applied inwardly at opposing side walls 20 and 22 causing the top wall 18 of the body 12 to bend about a central axis as the side walls 20 and 22 move toward one another. Once the side walls 20 and 22 are released or the pressure is no longer applied inwardly at the opposing side walls 20 and 22, the side walls 20 and 22 spring back to their original or relaxed position.

Alternatively, the side walls 20 and 22 are capable of moving inward when squeezed or an inward pressure is applied. Again, once released, the side walls 20 and 22 spring back to their original or relaxed orientation.

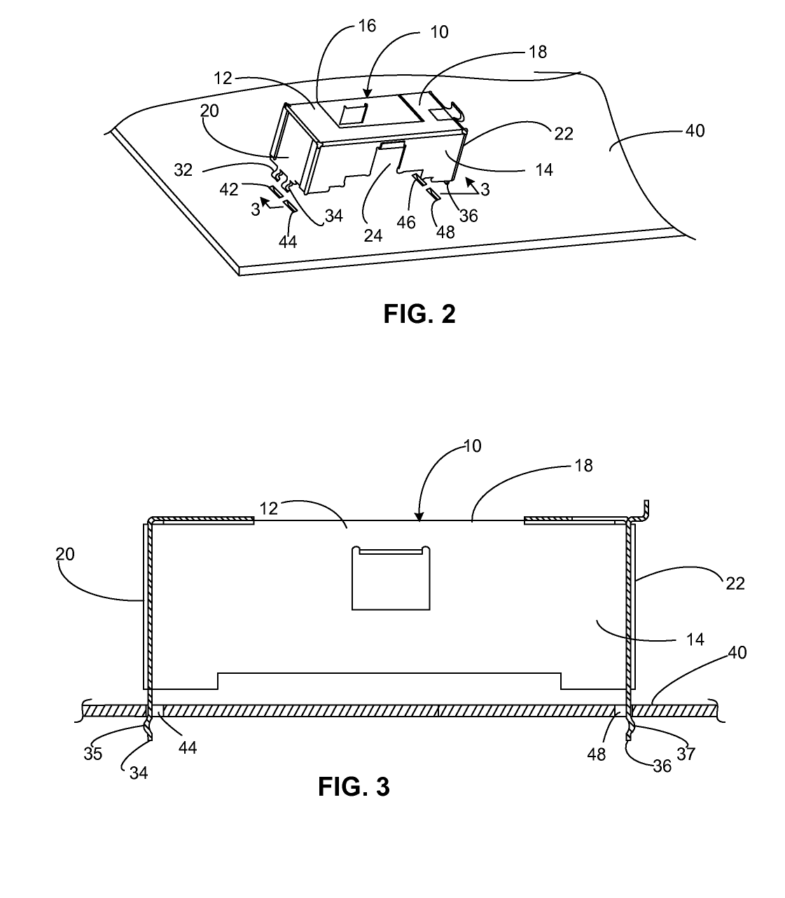

Turning to FIGS. 2 and 3, a PWB 40 is shown to include four mounting holes 42, 44, 46 and 48 sized and spaced apart to receive and secure the legs 32, 34 and 36 of the attachment mechanism 30. As depicted in FIG. 3, the legs 34 and 36 included bowed regions 35 and 37 bowing outwardly relative to the side walls 20 and 22 such that once received in the mounting holes 44 and 48 and the side walls 20 and 22 are released and no longer under pressure, the legs 34 and 36 press against the side walls of the mounting holes 44 and 28 while the bowed regions 35 and 37 of the legs 34 and 36 are positioned beyond the mounting holes 44 and 48 acting as stops abutting the PWB 44 to retain the shield 10 on the PWB 40 and prevent it from being dislodged.

In operation, the installer squeezes the sides 20 and 22 of the shield 10 inward slightly, enough to insert the shield legs 32, 34 and 36 (and a fourth not shown)into and extend through the mounting holes 42, 44, 46 and 48 formed in the PWB 40 with the bowed regions 35 and 37 positioned beyond the holes 42, 44, 46 and 48. After inserting the legs 32, 34 and 36 into the mounting holes 42, 44, 46 and 48, the installer releases the sides 20 and 22 of the shield 10, thus allowing the pressure of the mounting legs 32, 34 and 36 to be applied to the side surfaces of the mounting holes 42, 44, 46 and 48 and while the bowed regions 35 and 37 abut the PWB 40 to prevent the shield from being inadvertently dislodged from the PWB 40 during processing, assembly, and the like.

In the foregoing specification, the invention has been described with reference to specific embodiments thereof. It will, however, be evident that various modifications and changes may be made thereto without departing from the broader spirit and scope of the invention. For example, the reader is to understand that the specific ordering and combination of process actions shown in the process flow diagrams described herein is merely illustrative, unless otherwise stated, and the invention can be performed using different or additional process actions, or a different combination or ordering of process actions. As another example, each feature of one embodiment can be mixed and matched with other features shown in other embodiments. Features and processes known to those of ordinary skill may similarly be incorporated as desired. Additionally and obviously, features may be added or subtracted as desired. Accordingly, the invention is not to be restricted except in light of the attached claims and their equivalents.

What is claimed is:

1. A shield for a printed wiring board comprising
a deformable body adapted to deform under an applied pressure and maintain a spring bias while under the applied pressure to return to its original shape when the applied pressure is removed, and
two or more mounting legs extending from the body to releasably mount the body to a printed wiring board.

2. The shield of claim 1 where in the body is formed from a compliant conductive material.

3. The shield of claim 2 where in the compliant conductive material is a metal.

4. The shield of claim 1 where in the two or more mounting legs include a stop formed there on.

5. The shield of claim 4 where in the stop comprises a bowed region formed in the two or more mounting legs.

6. The shield of claim 1 where in the body has an open sided box shape.

7. The shield of claim 7 where in the body includes front and back walls, a top wall and first and second side walls.

8. The shield of claim 7 where in the body further comprises a passageway formed in the front and back walls.

9. An electronic device comprising
a housing,
a printed wiring board (PWB) located within the housing and including one or more electrical components coupled thereto, and
a shield releasably coupled the PWB, wherein the shield includes a deformable body adapted to deform under an applied pressure and return to its original shape when the applied pressure is removed.

10. The electronic device of claim 9 wherein the PWB includes two or more mounting holes and the shield includes two or more mounting legs extending from the body and insertable into the two or more mounting holes to releasably couple the body to the PWB.

11. The electronic device of claim 9 where in the body is formed from a compliant conductive material.

12. The electronic device of claim 11 where in the compliant conductive material is a metal.

13. The electronic device of claim 10 where in the two or more mounting legs include a stop formed there on.

14. The electronic device of claim 13 where in the stop comprises a bowed region formed in the two or more mounting legs.

15. The electronic device of claim 13 where in the stop is positioned beyond the hole and abutting the PWB.

16. The electronic device of claim 9 where in the body has an open sided box shape.

17. The electronic device of claim 16 where in the body includes front and back walls, a top wall and first and second side walls.

18. The electronic device of claim 17 where in the body further comprises a passageway formed in the front and back walls.
